(19) United States
(12) Patent Application Publication
(10) Pub. No.: US 2007/0252257 A1
(43) Pub. Date: Nov. 1, 2007

(54) SEMICONDUCTOR PACKAGE STRUCTURES HAVING HEAT DISSIPATIVE ELEMENT DIRECTLY CONNECTED TO INTERNAL CIRCUIT AND METHODS OF FABRICATING THE SAME

(75) Inventors: Joong-Hyun BAEK, Gyeonggi-do (KR); Hee-Jin LEE, Gyeonggi-do (KR); Hae-Hyung LEE, Gyeonggi-do (KR); Sun-Won KANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/741,623

(22) Filed: Apr. 27, 2007

(30) Foreign Application Priority Data
Apr. 27, 2006 (KR) 10-2006-0038204

(51) Int. Cl. H01L 23/02

(52) U.S. Cl. 257/678

(57) ABSTRACT

In one embodiment, a semiconductor package structure includes a heat dissipative element connected to an internal circuit. The semiconductor package includes a semiconductor chip, an interconnection substrate, and a heat dissipative element. The semiconductor chip includes an internal circuit and inner pads that connect the internal circuit. The interconnection substrate is disposed below the semiconductor chip and includes input/output terminals. At least one of the inner pads is electrically connected to at least one of the input/output terminals. The heat dissipative element is disposed on the semiconductor chip and is electrically connected to at least one of the inner pads.

### CROSS-REFERENCE TO RELATED APPLICATIONS

This U.S. non-provisional patent application claims priority under 35 U.S.C. § 119 from Korean Patent Application No. 10-2006-0038204, filed on Apr. 27, 2006, the entire contents of which are hereby incorporated by reference.

### BACKGROUND

1. Technical Field

This disclosure relates to a semiconductor package and a fabricating method thereof, and more particularly, to a semiconductor package having a heat dissipative element directly connected to an internal circuit.

2. Description of the Related Art

Semiconductor fabrication processes typically include a front-end process (that integrates integrated circuit (IC) chips on a wafer through photolithography, deposition, and etching processes) and a back-end process that assembles and packages each of the IC chips. Four important functions served by assembly and packaging are listed below.

1. Protecting the chips from environmental and handling damage

2. Forming lines on the chips for input/output signals

3. Physically supporting the chips

4. Heat dissipation for the chips

Furthermore, due to the proliferation of high integration and portable electronic devices, semiconductor packaging technology with improved electrical capabilities, reduced cost, lighter weight, and slimmer profiles are in demand. To satisfy these technical needs, package on package (POP), chip scale packaging (CSP), and wafer-level packaging (WLP) have recently been introduced. However, in the case of central processing units (CPU) and similar semiconductor chips, rapid technological progress in terms of speed and density has led to a sudden increase in power consumption. Accordingly, a package structure capable of effectively dissipating heat generated inside a chip is needed.

To protect a chip from environmental and handling damage, a method disclosed in the related art includes enclosing a semiconductor chip with epoxy or similar material. However, due to this material having low heat conductivity, the heat generated within the chip cannot effectively be dissipated. A further package structure of the related art involves installing a heat dissipative element made of a metal on the outside of a packaged chip. However, in this case as well, a material with low heat conductivity is used to adhere the heat dissipative element to the semiconductor chip, so that the adhering material acts as an insulator between the device and the chip, reducing the effect of the heat dissipating device. Consequently, a need remains for a package structure capable of effectively dissipating heat generated inside a semiconductor chip.

### SUMMARY

This disclosure provides a package structure capable of effectively dissipating heat generated by a semiconductor chip. This disclosure also provides a method for manufacturing a package capable of effectively dissipating heat generated by a semiconductor chip.

### BRIEF DESCRIPTION OF THE FIGURES

The accompanying figures are included to provide a further understanding of the invention, and are incorporated in and constitute a part of this specification. The drawings illustrate exemplary embodiments of the invention and, together with the description, serve to explain principles of the invention. In the figures:

FIGS. 1 through 4 are cross-sectional views of semiconductor chip package structures according to embodiments of the present invention;

FIG. 5 is a detailed sectional view of a semiconductor chip package structure showing a redistribution structure according to an embodiment of the present invention;

FIG. 6 is a flowchart of a manufacturing method of a package structure according to an embodiment of the present invention;

FIGS. 7 and 8 are cross-sectional views showing manufacturing steps of a package structure according to an embodiment of the present invention;

FIG. 9 is a flowchart of a manufacturing method of a package structure according to another embodiment of the present invention;

FIGS. 10 and 11 are cross-sectional views showing manufacturing steps of a package structure according to another embodiment of the present invention; and

FIG. 12 is a perspective view of a package structure, showing its assembly, according to some embodiments of the present invention.

### DETAILED DESCRIPTION

Preferred embodiments of the invention will be described below in more detail with reference to the accompanying drawings. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when a layer (or film) is referred to as being ‘on’ another layer or substrate, it can be directly on the other layer or substrate, or intervening layers may also be present. In the figures, the dimensions of layers and regions are exaggerated for clarity of illustration. It will be understood that although the terms first and second are used herein to describe various regions, layers and/or sections, these regions, layers and/or sections should not be limited by these terms. These terms are only used to distinguish one region, layer or section from another region, layer or section. Thus, for example, a first layer discussed below could be termed a second layer, and similarly, a second layer may be termed a first layer without departing from the teachings of the present invention. Hereinafter, exemplary embodiments of the present invention will be described in conjunction with the accompanying drawings.

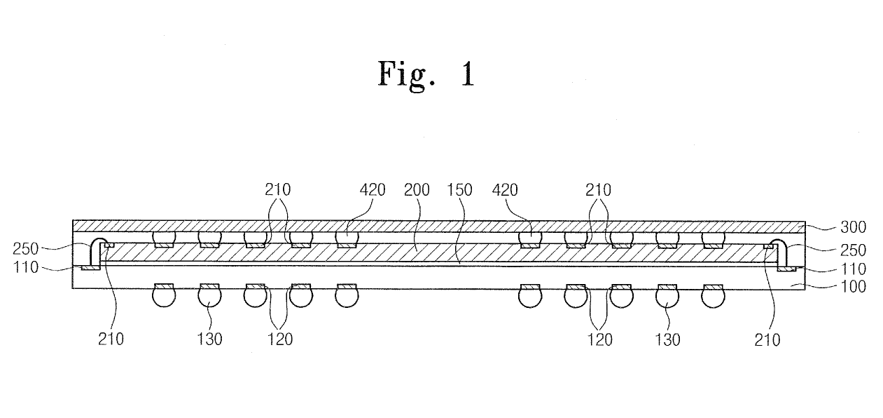

FIGS. 1 through 4 are cross-sectional views of a semiconductor chip package structure according to some embodiments of the present invention.

Referring to FIG. 1, a semiconductor chip package structure according to one embodiment of the present invention includes an interconnection substrate 100, a semiconductor chip 200 mounted on the interconnection substrate 100, and a heat dissipative element 300 disposed on the semiconductor chip 200.

The interconnection substrate 100 includes inner input/output terminals 110 for electrically connecting to the semiconductor chip 200, outer input/output terminals 120 for electrically connecting to an external electronic device (not shown), and interconnections (not shown) for connecting the inner and outer input/output terminals 110 and 120. A predetermined adhesive 150 may be disposed between the interconnection substrate 100 and the semiconductor chip 200 to adhere them together.

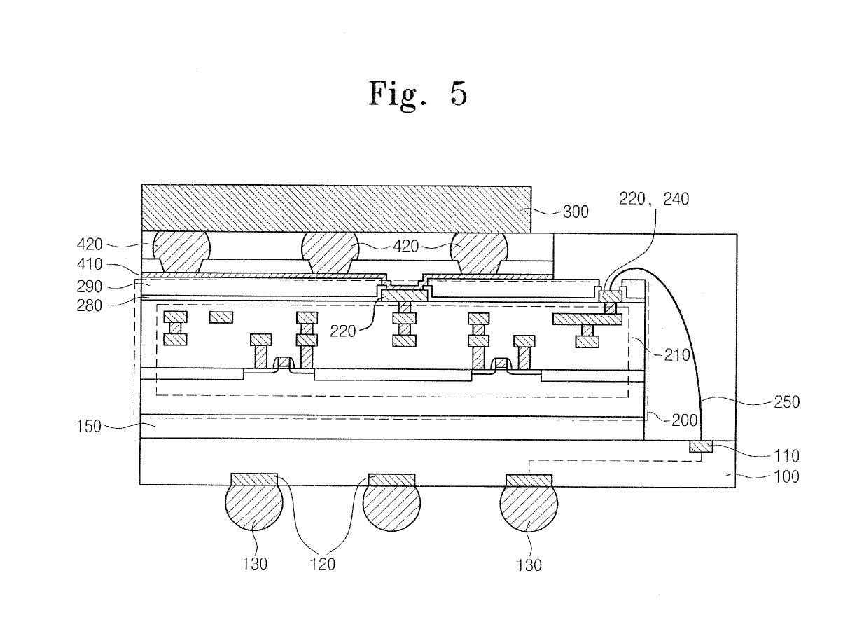

In order for the semiconductor chip 200 to perform its function, it includes an internal circuit 210 (in FIG. 5) and inner pads 220 electrically connected to the internal circuit 210. The internal circuit 210 includes an inner interconnection structure for connecting a semiconductor device, resistor, capacitor, and similar microelectronic devices, and connecting these microelectronic devices to the inner pads 220. The inner interconnection structure includes wire lines and plugs between the wire lines, where the wire lines and plugs are formed of conductive materials.

The semiconductor chip 200 includes a bonding pad 240 that is used as an electrically connecting path between the internal circuit 210 and the interconnection substrate 100. In the first embodiment of the invention, a portion of the inner pads 220 may be used as the bonding pads 240. Also, the bonding pads 240 are electrically connected to an inner input/output terminal 110 through wires 250 formed in a wire bonding process.

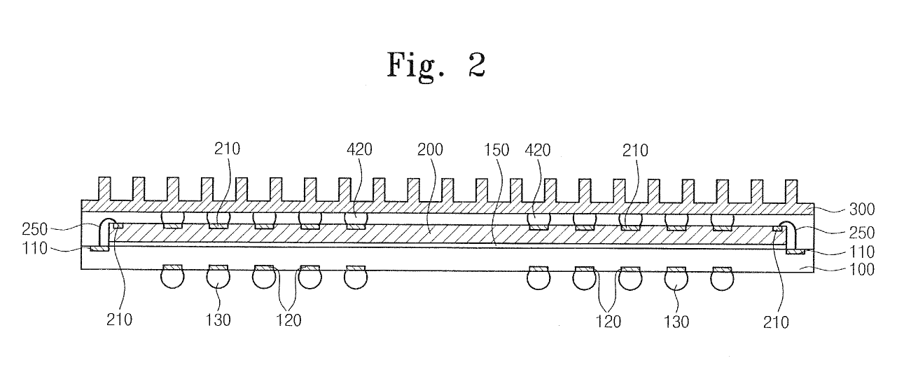

The heat dissipative element 300 may be one of a heat spreader, a heat sink, a thermal electronic cooler, or a heat pipe, and may be formed of a metal material with favorable thermal conductivity. The heat dissipative element 300 shown in FIG. 2 is a heat sink. The heat sink of FIG. 2 includes a plurality of ridges or fins 305 extending above a surface thereof, that provide increased surface area for heat dissipation to the air. The thermal electronic cooler uses the Peltier effect, and may be made of one of germanium, silicon, lead-tellurium, Bismuth-tellurium, and Indium-Phosphide. Furthermore, to achieve effective cooling, the heat dissipative element 300 is exposed to an environment with a relatively low temperature—for example, the outside air or a cooling device. The heat dissipative element 300 according to the first embodiment of the invention is exposed to the outside air.

According to the invention, the heat dissipative element 300 is disposed on the semiconductor chip 200, as described above, uses a predetermined conductive pattern (for example, a redistribution structure described below), and is electrically connected to at least one of the inner pads 220. Accordingly, a conductive path for interconnection is formed between the heat dissipative element 300 and the internal circuit 210, and includes the conductive pattern and the inner pads 220. As a result, the heat generated from the inside of the semiconductor chip 200 (more precisely, the internal circuit 210) can be dissipated much more effectively than in a conventional device lacking this type of conductive connecting path. In more detail, the inner heat energy is dissipated to the outside air through the movements of electrons and the transfer of phonons, and the conductive path for interconnection is helpful as a transfer mechanism of this energy to expedite the transferring process.

To form this conductive path for interconnection, the invention may dispose a redistribution structure between the semiconductor chip 200 and the heat dissipative element 300. FIG. 5 is a detailed sectional view of a semiconductor chip package structure showing a redistribution structure according to an embodiment of the invention.

Referring to FIG. 5, the redistribution structure includes upper lines 410 connected to the inner pads 220, and upper bumps 420 disposed above the upper lines 410. In further detail, a protective layer for exposing the upper surface of the inner pads 220 may be disposed between the upper lines 410 and the semiconductor chip 200. The protective layer, as shown in FIG. 5, includes a first protective layer 280 and a second protective layer 290 stacked on the first protective layer 280. Here, the first protective layer 280 may be at least one of a silicon oxide layer or a silicon nitride layer, and the second protective layer 290 may be at least one of polyimide, polyetherimide, epoxy resin, silicon resin, and photosensitive resin.

The upper lines 410 are electrically connected to at least one of the power pad, ground pad, and signal pads of the semiconductor substrate 200 through the inner pads 220. (Here, the power pad, ground pad, and signal pads are inner pads that supply an electrical voltage, a ground voltage, and a signal voltage, respectively, within the internal circuit 210.) The semiconductor chip 200 may include a plurality of power pads and/or ground pads to supply a stable voltage. In this case, the number of conductive connections between the heat dissipative element 300 and the internal circuit 210 increases, so that inner heat energy can be more effectively dissipated.

The electrical voltage and the ground voltage are statically supplied, so that the upper lines 410 may be connected to the ground pad or the power pad. Also, in order to prevent damage to the semiconductor chip 200 from electrostatic discharge (ESD), the internal circuit 210 may include an ESD prevention circuit connected to the inner pads 220, which are connected to the upper lines 410. The ESD prevention circuit may be a conventional ESD prevention circuit, and may be disposed between the inner pads 220 and the microelectronic devices in the internal circuit 210.

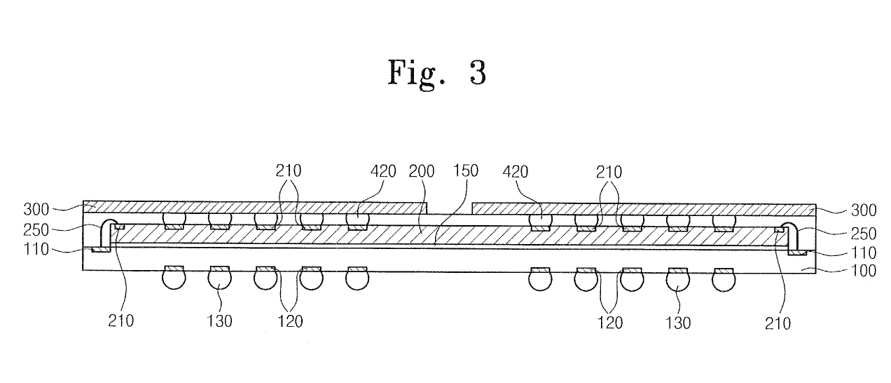

The upper lines 410 may be connected to at least two of the power pad, ground pad, and signal pads. In this case, in order to prevent a short, the heat dissipative element 300 may be formed in two divided parts, which are respectively connected to different inner pads 220, as shown in FIG. 3. In other words, the heat dissipative element 300 may include a first heat dissipating member 300a and a second heat dissipating member 300b that are electrically isolated from each other. At least some of the upper lines 410 may be used as bonding pads 240, in which case the upper lines 410 that are used as bonding pads 240 are electrically separated from the heat dissipative element 300. In this case, the bonding pads 240 may be disposed on the outer edge of the upper surface of the semiconductor chip 200.

When the upper bumps 420 are disposed above the upper lines 410, a plurality of upper bumps 420 may be disposed above one upper line 410. Thus, the resistance between the heat dissipative element 300 and the upper lines 410 decreases, and the adhesion therebetween increases. The redistribution structure may be formed using conventional methods (for example, the method disclosed in Korean Patent No. 2003-0050496, which is hereby incorporated by reference in its entirety).

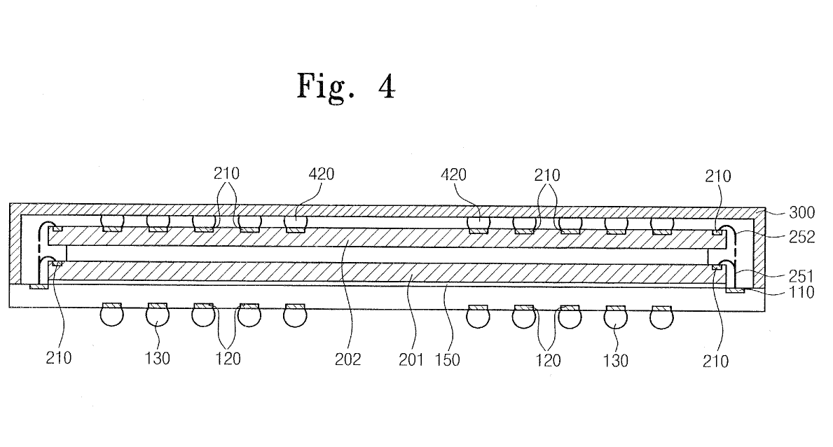

FIG. 4 is a cross-sectional view of a package structure of a semiconductor package according to an embodiment of the invention. Aside from a plurality of semiconductor chips 201, 202 being disposed between the interconnection substrate 100 and the heat dissipative element 300, this embodiment is the same as the last embodiment. Therefore, repetitive descriptions thereof will be omitted. Furthermore, while there are two semiconductor chips 201, 202 disposed between the interconnection substrate 100 and the heat dissipative element 300 in this embodiment, there may be a larger number of semiconductor chips employed in this embodiment.

Referring to FIG. 4, in this embodiment, first and second semiconductor chips 201 and 202 are sequentially stacked on the interconnection substrate 100. The first and second semiconductor chips 201 and 202 each include an internal circuit, an interconnection structure connected to the internal circuit, and inner pads 220 for connecting to an external device, as described above. The first and second semiconductor chips 201 and 202 are respectively connected electrically to the interconnection substrate 100 through first and second wires 251 and 252.

The first and second semiconductor chips 201 and 202 and the package structure in the form of the interconnection substrate 100 may use a conventional packaging technology. For example, the first and second semiconductor chips 201 and 202 according to this embodiment may use conventional package structures with a plurality of semiconductor chips (such as those disclosed in U.S. Pat. No. 6,869,827, U.S. Pat. No. 6,680,212, and Japanese Patent No. 2001-015679, which are hereby incorporated by reference in their entirety), to become a package for the interconnection substrate 100.

According to this embodiment, an upper semiconductor chip (that is, the second semiconductor chip 202) may include the redistribution structure described above, and the heat dissipative element 300 is attached at the top thereof. As described, the heat dissipative element 300 is electrically connected to the second semiconductor chip 202 through the redistribution structure. As a result, heat generated from the upper semiconductor chip 202 can easily be dissipated to the outside air.

According to this embodiment, the heat dissipative element 300 may be disposed to enclose the sidewalls of the first and second semiconductor chips 201 and 202. In this case, the heat dissipative element 300 may be electrically separated from the inner input/output terminals 110 of the interconnection substrate 100, to prevent a short. It is apparent that the first semiconductor chip 201 directly attached to the interconnection substrate 100 is better able to dissipate heat from inside than the second semiconductor chip 202. Thus, a package structure that can effectively dissipate heat from the second semiconductor chip 202 is required, a requirement that the heat dissipative element 300 fulfills.

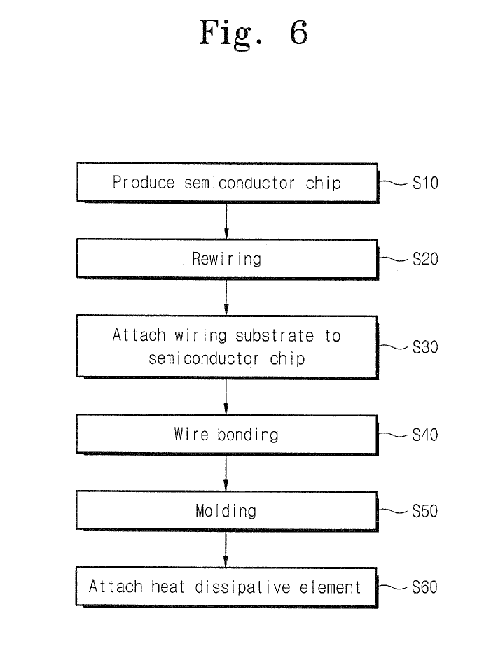

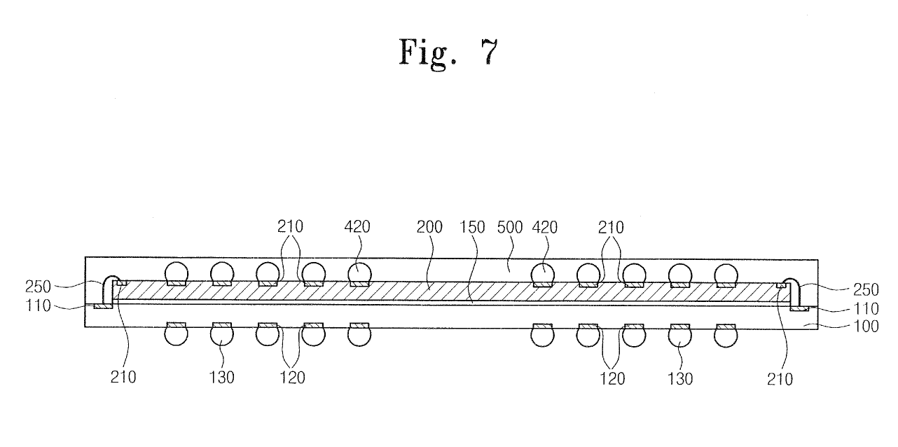

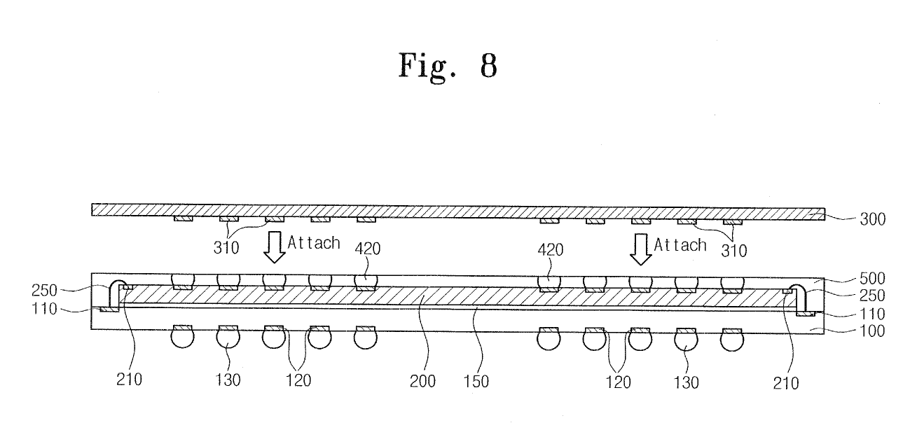

FIG. 6 is a flowchart of a manufacturing method of a package structure according to an embodiment of the invention. FIGS. 7 and 8 are cross-sectional views showing manufacturing steps of a package structure according to an embodiment of the invention.

Referring to FIGS. 6 through 8, after a semiconductor chip 200 is manufactured, a redistribution (or rewiring) process is performed to form a redistribution structure including upper bumps 420 on top of the semiconductor chip 200 in steps S10 and S20. The semiconductor chip 200 with the redistribution structure is attached to an interconnection substrate 100 with inner and outer input/output terminals 110 and 120 in step S30. For this attachment, an adhesive 150 shown in FIGS. 1 through 5 may be used. Next, a wire bonding process is performed to electrically connect the semiconductor chip 200 to the interconnection substrate 100 in step S40.

Then, referring to FIG. 7, a molding layer 500 for covering the wire 250 and the semiconductor chip 200 is formed in step S50. The molding layer 500 may be formed of at least one of a polyimide, polyetherimide, epoxy resin, and silicon resin. Next, as shown in FIG. 8, the molding layer 500 is etched to expose the upper bumps 420, and the heat dissipative element 300 is attached and connected to the exposed upper bumps 420. For this attachment, conductive connecting patterns 310 may be disposed below the heat dissipative element 300, corresponding to the positions of the upper bumps 420 to facilitate high-quality electrical and physical connections between the heat dissipative element 300 and the upper bumps 420.

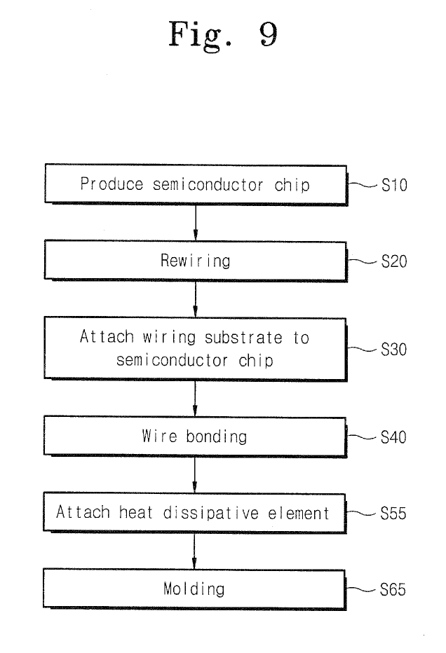

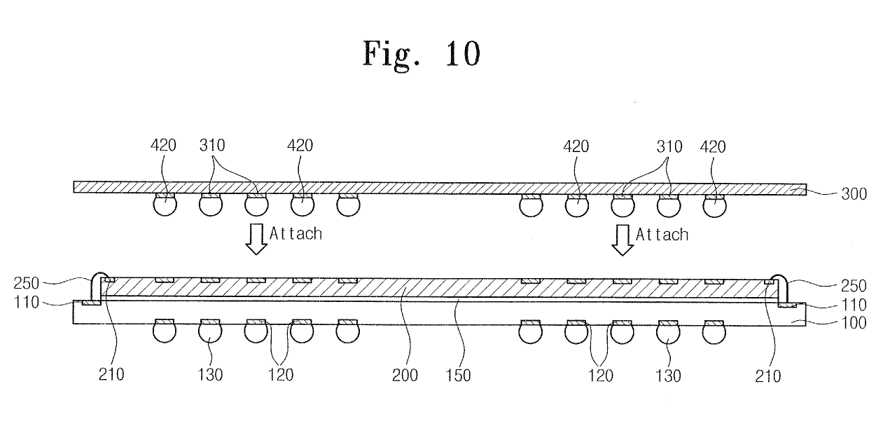

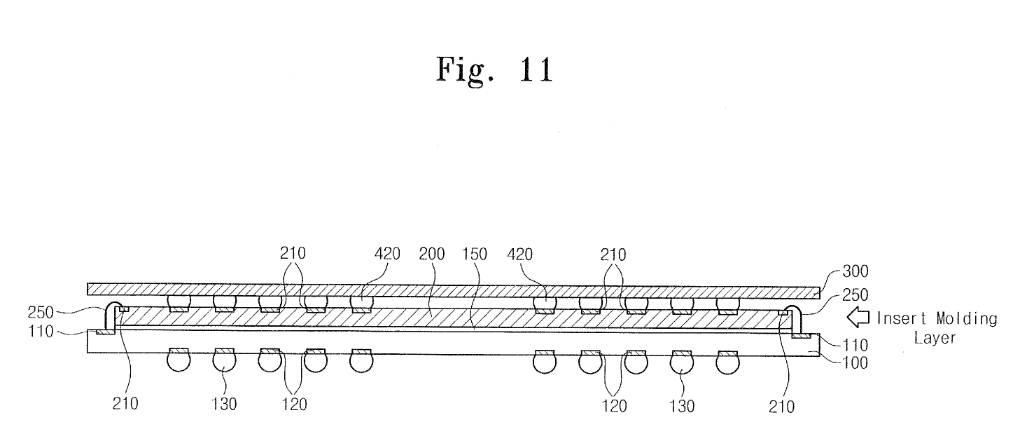

FIG. 9 is a flowchart of a manufacturing method of a package structure according to another embodiment of the invention. FIGS. 10 and 11 are cross-sectional views showing manufacturing steps of a package structure according to this embodiment of the invention. Besides the forming of the molding layer following the attaching of the heat dissipative element, this embodiment is the same as the embodiment described in FIGS. 6 through 8. Thus, repetitive descriptions are omitted below.

Referring to FIGS. 9 through 11, after a wire bonding process is performed in step S40, the heat dissipative element 300 is attached to the top of the semiconductor chip 200 in step S55. In more detail, the upper bumps 420 are arranged on the lower surface of the heat dissipative element 300, and a redistribution structure is formed on top of the semiconductor chip 200 for electrically connecting the upper bumps 420. In this embodiment of the invention, the upper bumps 420 may be a portion of the redistribution structure on top of the semiconductor chip 200, as in previous embodiments. The upper bumps 420 are used to electrically and physically connect the heat dissipative element 300 and the semiconductor chip 200. Next, a molding layer 500 filling the space between the heat dissipative element 300 and the semiconductor chip 200 is formed in step S65. The molding layer 500 may also fill the space between the heat dissipative element 300 and the interconnection substrate 100. As a result, the wire 250 and the semiconductor chip 200 are covered by the molding layer 500.

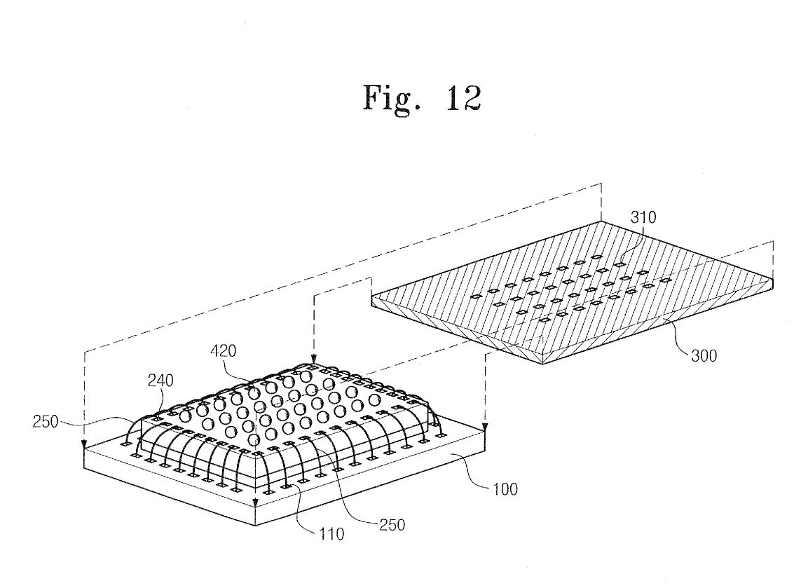

FIG. 12 is a perspective view of a package structure, showing its assembly, according to some embodiments of the invention.

Referring to FIG. 12, a package structure includes a semiconductor chip 200 disposed on an interconnection substrate 100. An adhesive 150 may be disposed between the interconnection substrate 100 and the semiconductor chip 200. The interconnection substrate 100 includes inner input/output terminals 110, which may be connected to bonding pads 240 by wires 250. Upper bumps 420 are disposed on the semiconductor chip 200. According to some embodiments, a redistribution structure may be disposed between the semiconductor chip 200 and the upper bumps 420. Heat dissipative element 300 may include conductive connecting patterns 310. As shown by the dotted lines in FIG. 12, the heat dissipative element 300 is attached on the semiconductor chip 200 such that the conductive connecting patterns 310 are connected to the upper bumps 420. In this way, the heat dissipative element 300 is physically and electrically connected to the semiconductor chip 200.

The internal circuit of a semiconductor chip according to the invention is electrically connected to a heat dissipative element that is exposed to outside air through predetermined conductive patterns (for example, a redistribution structure). Therefore, the heat generated by the semiconductor chip can effectively be dissipated to the outside air.

Embodiments of the invention provide a semiconductor package structure having a heat dissipative element directly connected to the internal circuit of the semiconductor chip. The semiconductor package includes: a semiconductor chip including an internal circuit and inner pads connected to the internal circuit; an interconnection substrate disposed below the semiconductor chip and including input/output terminals; at least one wire for connecting at least one of the inner pads to the input/output terminals; and a heat dissipative element disposed on the semiconductor chip and electrically connected to at least one of the inner pads.

In some embodiments, the semiconductor package may further include a redistribution structure disposed between the heat dissipative element and the semiconductor chip, for connecting the heat dissipative element and the inner pads. The inner pads may include a power pad for connecting a power voltage, a ground pad for connecting a ground voltage, and a plurality of signal pads for connecting signal voltages; and the redistribution structure may include upper lines disposed on the semiconductor chip and connected to the internal circuit through the inner pads, and at least one upper bump disposed on at least one of the upper lines and connecting the inner pads.

In other embodiments, the redistribution structure may further include at least one bonding pad for bonding to the wire, and the at least one bonding pad may be disposed on an upper surface perimeter of the semiconductor chip and may be electrically connected to the inner pads through the upper lines. The signal pads may be disposed on an upper surface perimeter of the semiconductor chip, and the wire may be bonded to the signal pads.

In still other embodiments, the heat dissipative element may be connected to the ground pad through the redistribution structure. Also, the heat dissipative element may be connected to the power pad through the redistribution structure. Further, the heat dissipative element may be connected to at least one of the signal pads through the redistribution structure. The heat dissipative element may be at least one of a heat spreader, a heat sink, a thermal electronic cooler, a heat pipe, and a conductive layer with high thermal conductivity.

In even other embodiments, the heat dissipative element may be separated from at least one of the input/output terminals and may cover top and side surfaces of the semiconductor chip. The heat dissipative element may be electrically connected to the internal circuit through one of the inner pads and exposed to outside air, for dissipating heat generated by the internal circuit of the semiconductor chip to the outside air through electron movement.

In yet other embodiments, the internal circuit may include: microelectronic devices including a semiconductor device, a resistor, and a capacitor; an inner interconnection structure electrically connecting the microelectronic devices to the inner pads; and at least one ESD (electrostatic discharge) preventing circuit, wherein the ESD preventing circuit may be disposed between the inner pads to which the heat dissipative element is connected and the microelectronic devices.

In further embodiments, the interconnection substrate may include: external input/output terminals for transmitting signals to and from an external electronic device; lines connecting the input/output terminals to the external input/output terminals; and lower bumps disposed below the external input/output terminals.

In other embodiments of the invention, methods for packaging a semiconductor chip for directly connecting an internal circuit of the semiconductor chip to a heat dissipative element are provided. The methods include: manufacturing a semiconductor chip including an internal circuit and inner pads connected to the internal circuit; performing a redistribution process for forming a redistribution structure including bonding pads connected to the inner pads; attaching the semiconductor chip with the redistribution structure formed thereon on an interconnection substrate including input/output terminals; connecting the bonding pads to the input/output terminals using a wire; and attaching a heat dissipative element electrically connected to the internal circuit through the redistribution structure and the inner pads on the redistribution structure.

In still other embodiments the forming of the redistribution structure may include: forming upper lines connected to the inner pads; and forming upper bumps on the upper lines. The method may further include: forming a protective layer covering the wire; and etching the protective layer and exposing the upper bumps, prior to the attaching of the heat dissipative element, wherein the attaching of the heat dissipative element includes electrically connecting the exposed upper bumps and the heat dissipative element. The method may further include filling a gap between the heat dissipative element and the interconnection substrate with a protective layer, after the attaching of the heat dissipative element.

The above-disclosed subject matter is to be considered illustrative, and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

What is claimed is:

1. A semiconductor package comprising:
an interconnection substrate including input/output terminals;
a semiconductor chip mounted on the interconnection substrate, the semiconductor chip including an internal circuit and inner pads connected to the internal circuit; and
a heat dissipative element disposed on the semiconductor chip and electrically connected to at least one of the inner pads,
wherein at least one of the inner pads is electrically connected to at least one of the input/output terminals.

2. The semiconductor package of claim 1, further comprising a redistribution structure disposed between the heat dissipative element and the semiconductor chip.

3. The semiconductor package of claim 2, wherein the inner pads include a power pad, a ground pad, and a plurality of signal pads; and
the redistribution structure includes upper lines disposed on the semiconductor chip and connected to the internal circuit through the inner pads, and at least one upper bump disposed on at least one of the upper lines and connected to the inner pads.

4. The semiconductor package of claim 3, wherein the redistribution structure further includes at least one bonding pad disposed on an upper surface of the semiconductor chip and electrically connected to at least one of the inner pads through the upper lines.

5. The semiconductor package of claim 3, wherein the signal pads are disposed on an upper surface of the semiconductor chip, and the wire is bonded to the signal pads.

6. The semiconductor package of claim 3, wherein the heat dissipative element is connected to the ground pad through the redistribution structure.

7. The semiconductor package of claim 3, wherein the heat dissipative element is connected to the power pad through the redistribution structure.

8. The semiconductor package of claim 3, wherein the heat dissipative element is connected to at least one of the signal pads through the redistribution structure.

9. The semiconductor package of claim 3, wherein the redistribution structure further comprises a first protective layer and a second protective layer disposed between the semiconductor chip and the upper lines.

10. The semiconductor package of claim 9, wherein the first protective layer comprises at least one of a silicon oxide layer and a silicon nitride layer, and the second protective layer comprises at least one of polyimide, polyetherimide, epoxy resin, silicon resin, and photosensitive resin.

11. The semiconductor package of claim 1, wherein the internal circuit comprises:
microelectronic devices including a semiconductor device, a resistor, and a capacitor;
an inner interconnection structure electrically connecting the microelectronic devices to the inner pads; and
at least one ESD (electrostatic discharge) preventing circuit,
wherein the ESD preventing circuit is disposed between the inner pads connected to the heat dissipative element and the microelectronic devices.

12. The semiconductor package of claim 1, wherein the heat dissipative element is at least one of a heat spreader, a heat sink, a thermal electronic cooler, a heat pipe, and a conductive layer with high thermal conductivity.

13. The semiconductor package of claim 1, wherein the heat dissipative element is separated from at least one of the input/output terminals and covers top and side surfaces of the semiconductor chip.

14. The semiconductor package of claim 1, wherein the heat dissipative element is electrically connected to the internal circuit through one of the inner pads and exposed to outside air, for dissipating heat generated by the internal circuit of the semiconductor chip to the outside air through movement of electrons.

15. The semiconductor package of claim 1, wherein the interconnection substrate comprises:
external input/output terminals;
conductive lines connecting the input/output terminals to the external input/output terminals; and
lower bumps disposed below the external input/output terminals.

16. The semiconductor package of claim 1, wherein the heat dissipative element comprises a first heat dissipating member and a second heat dissipating member and wherein the first heat dissipating member is electrically isolated from the second heat dissipating member.

17. The semiconductor package of claim 1, wherein the heat dissipative element comprises a plurality of ridges.

18. The semiconductor package of claim 1, further comprising a molding layer disposed between the heat dissipative element and the interconnection substrate.

19. The semiconductor package of claim 1, further comprising another semiconductor chip disposed between the interconnection substrate and the semiconductor chip.

20. A method for packaging a semiconductor chip, comprising:
providing a semiconductor chip including an internal circuit and inner pads connected to the internal circuit;
forming a redistribution structure on the semiconductor chip, the redistribution structure including bonding pads connected to the inner pads;
attaching the semiconductor chip with the redistribution structure on an interconnection substrate including input/output terminals;
connecting the bonding pads to the input/output terminals using a wire; and
disposing a heat dissipative element over the semiconductor chip such that the heat dissipative element is electrically connected to the internal circuit through the redistribution structure and the inner pads.

21. The method of claim 20, wherein forming the redistribution structure comprises:
forming upper lines connected to the inner pads; and
forming upper bumps on the upper lines.

22. The method of claim 21, wherein forming the redistribution structure further comprises forming a first protective layer and a second protective layer on the semiconductor chip before forming the upper lines.

23. The method of claim 21, further comprising, before attaching the heat dissipative element:
forming a molding layer covering the redistribution structure; and
etching the molding layer to expose the upper bumps,
wherein attaching the heat dissipative element includes electrically connecting the exposed upper bumps and the heat dissipative element.

24. The method of claim 21, further comprising, after attaching the heat dissipative element, forming a molding layer filling a gap between the heat dissipative element and the interconnection substrate and between the heat dissipative element and the semiconductor chip.

25. The method of claim 20, wherein the heat dissipative element is at least one of a heat spreader, a heat sink, a thermal electronic cooler, a heat pipe, and a conductive layer with high thermal conductivity.

26. The method of claim 20, wherein the heat dissipative element is electrically connected to the internal circuit through one of the inner pads and exposed to outside air, for dissipating heat generated by the internal circuit of the semiconductor chip to the outside air through a movement of electrons.

27. The method of claim 20, wherein the inner pads include a power pad, a ground pad, and a plurality of signal pads; and
the redistribution structure is formed to connect the heat dissipative element to at least one of the ground pad, the power pad, and the signal pads.

28. The method of claim 20, further comprising forming an adhesive on the interconnection substrate before attaching the semiconductor chip on the interconnection substrate.

29. The method of claim 20, wherein electrically connecting the bonding pads to the input/output terminals comprises wire bonding.

30. A method for packaging a semiconductor chip, the method comprising:
providing a semiconductor chip including an internal circuit and inner pads connected to the internal circuit;
mounting the semiconductor chip on an interconnection substrate including input/output terminals; and
disposing a heat dissipative element over the semiconductor chip such that the heat dissipative element is electrically connected to at least one of the inner pads of the internal circuit.

31. A semiconductor package comprising:
an interconnection substrate including input/output terminals;
a semiconductor chip mounted on the interconnection substrate, the semiconductor chip including an internal circuit and inner pads connected to the internal circuit;
at least one wire for connecting at least one of the inner pads to at least one of the input/output terminals; and
a heat dissipative element disposed on the semiconductor chip and electrically connected to at least one of the inner pads.
